(19) United States
(12) Patent Application Publication
(10) Pub. No.: US 2026/0310103 A1
(43) Pub. Date: Oct. 8, 2026

(54) RUN TO RUN OVERLAY COMPENSATION IN LITHOGRAPHY SEQUENCES EMPLOYING DIFFERENT LITHOGRAPHY METHODS

(71) Applicant: Taiwan Semiconductor Manufacturing Company, LTD., Hsinchu (TW)

(72) Inventors: Hsin-Yuan Lee, Hsinchu (TW); Yu-Luen Deng, Tainan (TW); Chih-Kai Yang, Taipei (TW); Hsuan-Chin Lu, Hsinchu (TW)

(21) Appl. No.: 19/170,176

(22) Filed: Apr. 4, 2025

(51) Int. Cl. G03F 7/00

(52) U.S. Cl. CPC G03F 7/70633; G03F 7/0002; G03F 7/70291

(57) ABSTRACT

In a lithographic method, a measured overlay error map is determined using metrology of a first pattern formed on an integrated circuit (IC) chip by a lithography step performed using a first lithography method. A set of feedforward terms of a first type corresponding to the first lithography method are determined from the measured overlay error map, and are then transformed to a set of feedforward terms of a second type corresponding to a lithography method different from the first lithography method. Overlay compensation for a lithography step to be performed using the second lithography method is determined using at least the set of feedforward terms of the second type. The first lithography method may be optical lithography and the second lithography method may be nano imprint lithography, or vice versa.

### BACKGROUND

The following relates to the semiconductor fabrication arts, lithography arts, advanced process control (APC) arts for controlling lithography operations in a semiconductor fabrication facility, and related arts.

Fabrication of a two-dimensional array of IC chips (i.e., dies) on a semiconductor wafer may involve performing a sequence of dozens or more lithography steps to pattern successive resist layers to control etching, deposition, dopant delivery, and/or other processing steps. Advanced process control (APC) may leverage metrology of previous wafers (or previous wafer lots) in a feedback control methodology, and/or may leverage metrology of a previous layer in the current wafer in a feedforward methodology, to provide overlay compensation enhancing accuracy of the sequence of lithography steps. However, nano imprint lithography (NIL) steps are incompatible with such an integrated circuit (IC) fabrication workflow.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 diagrammatically illustrates a portion of a semiconductor fabrication facility including an optical scanner for performing optical lithography, a nano imprint lithography (NIL) tool for performing NIL, and an advanced process control (APC) providing run to run (R2R) overlay compensation control and including an overlay compensation terms translator.

FIG. 2 diagrammatically illustrates a nonlimiting example of an APC including an overlay compensation terms translator.

FIG. 3 diagrammatically illustrates operation of the overlay compensation terms translator in an example in which the previous lithography step used optical lithography, and current lithography step is to use NIL.

FIG. 4 diagrammatically illustrates operation of the overlay compensation terms translator in an example in which the previous lithography step used NIL, and current lithography step is to use optical lithography.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments disclosed herein advantageously provide systems and methods for performing advanced process control (APC) with automatic overlay error compensation in semiconductor integrated circuit (IC) fabrication workflows that employ both optical lithography steps and nano imprint lithography (NIL) steps. To achieve this, the APC incorporates a translator to automatically translate between optical lithography settings (for example, expressed as k-terms) and NIL settings (for example, expressed as finger actuator settings and/or heat distribution settings).

Manufacture of a two-dimensional array of IC chips (i.e., dies) on a semiconductor wafer may involve performing a sequence of dozens or more lithography steps to pattern successive resist layers to control etching, deposition, dopant delivery, and/or other processing steps. For successful IC fabrication, the lithography patterns formed by the successive lithography steps should be spatially aligned for each IC chip of the two-dimensional array of IC chips. This is referred to as overlay of the mask (or reticle) and the wafer (or, more precisely, the previous lithography layer or layers of the IC chip under-fabrication). In practice, certain lithography patterns may include designated alignment marks or features (which may or may not be functional features of the IC chip) that enable measurement of the spatial position (translational, rotational, and possibly other geometric metrics such as distortion) of the last patterned layer formed. More particularly, after the first layer is lithographically patterned, each successive lithography layer should have precise spatial alignment between the new pattern and the previous patterned layer of the chip. Misalignment between the new pattern and the previously formed lithography pattern is referred to as overlay error. There are various types of overlay errors, such as translational misalignment, rotational misalignment, magnification error, various types of lens distortion, and so forth. The overlay error may result from a wide range of physical mechanisms, such as wafer warping due to different coefficients of thermal expansion (CTE) for different materials making up the IC chip undergoing fabrication, spatial thickness nonuniformities of deposited (or etched) layers over the area of the semiconductor wafer, additive (or aggregated) overlay errors over successive previous lithography steps, and/or so forth. Any overlay error is problematic: In a complex IC fabrication workflow including dozens or more successive lithography steps, the overlay errors from one lithography step to the next can accumulate, potentially leading to failure of some IC chips and reduced chip yield per semiconductor wafer.

APC is employed in IC fabrication facilities to compensate for overlay error over the course of a workflow that may include dozens or even hundreds of successive lithography steps. One type of APC is run-to-run (R2R) control, which leverages empirical wafer measurement data acquired during the IC fabrication workflow to determine overlay compensation for the current lithography step. R2R control utilizes measured data of the previous layer patterned on the current semiconductor wafer (or current wafer lot) which is currently undergoing the current lithography step. For example, the alignment marks or features of the last patterned layer can be measured using microscopy or the like. This type of R2R control may be referred to as feedforward control, since measurements of pattern produced in the previous lithography step in the processing of the current semiconductor wafer (or wafer lot) are being fed forward to the upcoming (i.e., current) lithography step.

Optionally, measurement data of the pattern produced in the current lithography step may be measured for previous semiconductor wafers (or wafer lots). This type of R2R control may be referred to as feedback control, since the measurement data of previous wafers (or wafer lots) is being fed back to be used in overlay error compensation for the current lithography step being performed on the current semiconductor wafer (or current wafer lot). Both feedback and feedforward control approaches can be combined in feedforward/feedback (FF/FB) R2R control.

The overlay compensation determined by R2R control corrects overlay error to obtain accurate alignment of the currently formed pattern with the pattern formed on the IC chip in the previous lithography step. The R2R control is performed on a per-chip basis—that is, different overlay compensation may in general be applied for each IC chip of a two-dimensional array of IC chips being fabricated on a single semiconductor wafer. Such a per-chip overlay compensation is appropriate since, as a nonlimiting illustrative example, different overlay compensation may be employed in response to wafer warpage to accurately align IC chips near the center of the two-dimensional array of IC chips being fabricated on the current semiconductor wafer, as compared with IC chips near the periphery of the two-dimensional array of IC chips being fabricated on the current semiconductor wafer. (And, indeed, different overlay compensation may be appropriate for different peripheral regions, and so forth).

Optical lithography uses a light-reflective or light-transmissive optical mask (or reticle) illuminated by a light source to form a latent image on photoresist previously deposited on the semiconductor wafer. Chemical processing (i.e., development) of the latent image forms openings where the light impinged on the photoresist (in the case of positive photoresist) or where the light did not impinge on the photoresist (in the case of negative photoresist). In general, the smallest dimension (i.e., critical dimension or CD) that is achievable is related to the wavelength of the light used in optical lithography. Deep ultraviolet (DUV) lithography can achieve a smaller critical dimension than longer-wavelength visible-light lithography, and still shorter-wavelength extreme ultraviolet (EUV) lithography can achieve a smaller critical dimension than DUV lithography. Optical lithography settings control the orientation (translational and rotation) of the latent image as well as its magnification. As an optical process, the latent image can be impacted by lensing effects such as lens distortion. Optical lithography is performed using an optical scanner (e.g., an EUV scanner for EUV lithography), and the optical scanner includes step-and-shoot functionality to enable the latent image to be formed on each IC chip of the two-dimensional array of IC chips being fabricated on the semiconductor wafer. The requisite overlay compensation in optical lithography may in some nonlimiting illustrative examples be represented by a parameterized polynomial function representing optical aberrations and/or wavefront errors, for example using Zernike polynomials, point spread function (PSF) or optical transfer function (OTF) polynomials, or so forth. In one nonlimiting illustrative example, the overlay compensation may be represented as:

$$dx = {k}_{1} + {k}_{3} * x + {k}_{5} * y + {k}_{7} * {x}^{2} + {k}_{9} * xy + {k}_{11} * {y}^{2} + {k}_{13} * {x}^{3} + {k}_{15} * {x}^{2} y + {k}_{17} * {xy}^{2} + {k}_{19} * {y}^{3} \qquad ( 1 )$$

$$and$$

$$dy = {k}_{2} + {k}_{4} * y + {k}_{6} * x + {k}_{8} * {y}^{2} + {k}_{10} * yx + {k}_{12} * {x}^{2} + {k}_{14} * {y}^{3} + {k}_{16} * {y}^{2} x + {k}_{18} * {yx}^{2} + {k}_{20} * {x}^{3} \qquad ( 2 )$$

In Equations (1) and (2), dx and dy are the x- and y-components of the overlay compensation, the coordinate (x, y) is the location in the optical lithography field (which roughly corresponds to the area of the IC die on which the latent image is to be formed), and the terms k₁, k₂, k₃, k₄, . . . , k₁₇, k₁₈, k₁₉, and k₂₀ are the k-terms. The overlay compensation for an optical lithography step can thus be represented by these k-terms. This is merely a nonlimiting illustrative example, and more generally the k-terms representing the overlay compensation for an optical lithography step are chosen based on the polynomial model used to represent the aberrations, wavefront errors or the like.

Nano imprint lithography (NIL) uses a stamp to mechanically imprint features on a resist layer disposed on the semiconductor wafer, such as a monomer or polymer resist. In a nonlimiting illustrative NIL process, the resist is spin coated onto the semiconductor wafer. The stamp is pressed onto the resist to mechanically transfer features of the stamp to the resist. While the stamp is pressed onto the resist, ultraviolet (UV) light is applied to cure the resist, after which the stamp is removed, leaving the cured resist with the mechanically transferred features. NIL can provide CD comparable to that obtainable by EUV lithography at a lower cost. As a mechanical process, NIL can be impacted by mechanical distortion of the stamp and/or semiconductor wafer, thermal expansion or contraction, and the like. To provide overlay compensation in NIL, the stamp is adjusted by finger actuators arranged to press against the lateral edges of the stamp. The finger actuators may be piezoelectric actuators, electrostatic actuators, micro-stepper motors (e.g., implemented using MEMS), or the like. By adjusting the forces applied by the respective finger actuators, translational and rotational adjustment of the stamp can be realized. If all the finger actuators press inward with increased force, this can provide negative magnification, whereas if all the finger actuators press inward with reduced force, this can provide positive magnification. To provide adjustment of the IC chip to implement NIL overlay compensation, a laser or other light source illuminates a digital mirror device (DMD) to apply different levels of light to different portions of the IC die to generate a heat distribution in the IC chip that leads to thermal expansion or contraction of the IC chip. Hence, the overlay compensation for an NIL step is represented by non-k-terms, such as a stamp deformation model to be implemented by action of the finger actuators and an IC chip thermal distortion model to be implemented by the DMD. NIL is performed using an NIL tool providing stepping functionality to enable the pattern to be pressed onto resist disposed on successive IC chips of the two-dimensional array of IC chips being fabricated on the semiconductor wafer.

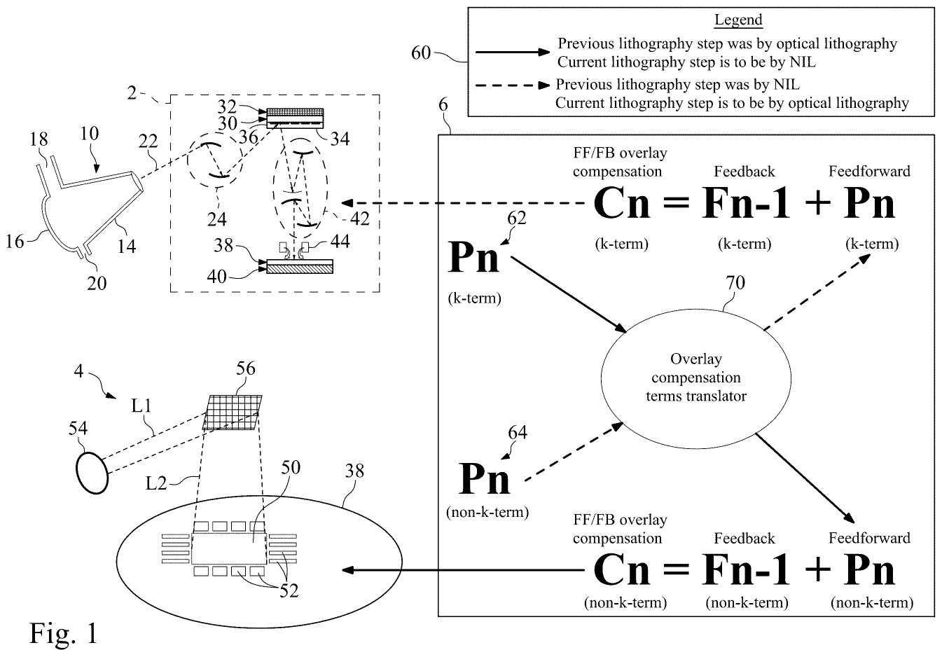

With reference to FIG. 1, a portion of a semiconductor fabrication facility is diagrammatically shown, including both an optical scanner 2 for performing optical lithography, and a nano imprint lithography (NIL) tool 4 for performing NIL. In the IC fabrication workflow, some lithography steps may be optical lithography steps performed using the optical scanner 2, and some lithography steps may be NIL steps performed using the NIL tool 4. An advanced process control (APC) 6 comprises a computer or other electronic processor operatively connected with the optical scanner 2 and NIL tool 4, and programmed to perform run-to-run (R2R) overlay compensation control for optical lithography steps performed using the optical scanner 2 and NIL steps performed using NIL tool 4. In the illustrative examples, the APC 6 employs both feedback (prelot) and feedforward (prelayer) overlay compensation (i.e., FF/FB control). However, it is contemplated for the APC to instead perform only feedforward control.

The illustrative optical scanner 2 (which may also be referred to herein as an optical lithography tool 2) is an extreme ultraviolet (EUV) scanner that is coupled with an EUV light source 10. The illustrative EUV light source 10 is a laser-produced plasma (LPP) EUV light source, such as a pulsed tin plasma EUV light source. In operation, the EUV light source 10 may be driven by a high power laser (not shown) such as a carbon dioxide (CO₂) laser or another pulsed laser that injects a pulsed laser beam into a vacuum chamber 14, for example, via an optical window. In some embodiments, the laser beam is injected from under or behind an EUV light collector mirror 16 and passes through a small hole, aperture or opening arranged at or near a center of the collector mirror 16. In some embodiments, the EUV light collector mirror 16 is a multi-layer construction forming a reflective mirror at and/or about the operative wavelength of the EUV light source 10. A target droplet generator (not shown) is installed at a vacuum port 18 of the vacuum chamber 14, and injects droplets of a target material (for example, tin) into the vacuum chamber 14. The target droplet is propelled toward a droplet catcher (not shown) installed at a port 20 opposite the port 18. The optical pulses of the laser are timed to impinge on the target droplets (for example, at or near the ignition site) as they pass through a focus of the EUV light collector mirror 16 to produce a plasma which generates extreme ultraviolet EUV light. In the case of tin droplets, for example, the EUV light has a spectrum centered at about 13.5 nm. More generally, the generated EUV light may be centered at a chosen wavelength in an EUV range between about 1 nm and about 100 nm. The collector mirror 16 reflects and focuses the plasma-generated EUV light to form EUV light 22 that exits the EUV light source 10 and passes into the EUV scanner 2. It is to be appreciated that this is a nonlimiting illustrative example, and that more generally another type of EUV light source may be utilized, such as by way of a further nonlimiting example an EUV light source employing a rotating annular crucible whose inside surface carries the tin or other target material.

As further shown in FIG. 1, the EUV scanner 2 comprises a vacuum chamber (diagrammatically indicated as a dashed box in FIG. 1) containing an illumination module 24 which is arranged to receive the EUV light. The illumination module 24 includes one or more optical elements (for example, EUV-reflective mirrors) that direct the EUV light 22 onto an EUV photolithography mask (or reticle) 30 mounted on a photomask holder 32, such as an electrostatic chuck. The photomask 30 has a pattern of EUV-reflective and EUV-absorbing regions, forming an image that is to be transferred as a latent image to a photoresist layer on an IC chip of a semiconductor wafer 38 that is disposed in the vacuum chamber on a wafer holder 40, which may for example comprise an electrostatic chuck for holding the wafer 38. The sensitive patterned surface of the photomask 30 is optionally protected by a pellicle 34 that is mounted on the front of the photomask 30 by a frame 36 that spaces the pellicle 34 away from the front of the photomask 30 by a defined distance. A projection module 42 of the EUV scanner 2 projects the EUV reflected from the EUV mask 30 onto the semiconductor wafer 38 (and more particularly onto an IC chip undergoing fabrication thereon) to form a latent image on and/or in a photoresist layer coating the semiconductor wafer 38. The projection module 42 includes a plurality of EUV-reflective mirrors arranged to project an image of the photomask 30 onto the photoresist coating the semiconductor wafer 38 to form the latent image of the pattern of EUV reflective and absorbing regions of the photomask 30 on and/or in the EUV light-sensitive photoresist. This constitutes an EUV photolithography exposure. The EUV scanner 2 is configured to perform step-and-shoot EUV photolithography exposures to form a two-dimensional array of latent images of the photomask 30 on and/or in the photoresist coating the semiconductor wafer 38 at respective IC chips.

While not shown in FIG. 1, it will be understood that, after the EUV photolithography exposure (or exposures) is complete, the semiconductor wafer 38 is removed from the EUV scanner 2, and a developer is applied to develop the latent image by etching away those portions of the photoresist that were exposed to the EUV light (this is the case for a positive EUV photoresist); or conversely by etching away those portions of the photoresist that were not exposed to the EUV light (this is the case for a negative EUV photoresist). The developing produces a pattern of openings in the developed photoresist, through which subsequent semiconductor processing steps such as etching, deposition, or the like are performed to form semiconductor device structures or the like in photolithographically controlled areas.

Additionally, metrology may be performed after the development to determine any overlay error, from which updated overlay compensation k-terms are computed for use in performing the lithography step on subsequent wafers (feedback compensation, denoted herein as Fn-1), and/or for use in the next lithography step on the current wafer (feedforward compensation, denoted herein as Pn). The metrology may in some embodiments be entirely automated, for example using an overhead hoist transport (OHT) or the like to transfer a front opening unified pod (FOUP) or other wafer carrier from the optical scanner 2 to a developer tool, and from the developer tool to a microscope or other metrology tool to perform the metrology, with robotic wafer transfer apparatuses loading wafers into and unloading wafers from the respective optical scanner 2, developer tool, and metrology tool.

Turning now to the NIL tool 4, this tool performs a lithography step (i.e., an NIL step) in a different manner. A stamp 50 is pressed against the semiconductor wafer 38 (which in some workflows may be the same wafer 38 depicted as being processed in the optical scanner 2, if for example an NIL step performed by the NIL tool 4 follows an optical lithography step performed by the optical scanner 2, or vice versa). The stamp 50 has a predefined pattern which is to be imprinted on a resist layer that is coating the semiconductor wafer 38. While the stamp 50 is pressed onto the resist, ultraviolet (UV) light (or another curing illumination) is applied to cure the resist, after which the stamp 50 is removed, leaving the cured resist with the mechanically transferred features.

To implement overlay compensation in the NIL tool 4, a set of piezoelectric finger actuators (or another type of finger actuators) 52 are arranged to press against the edges of the stamp 50, and by adjusting the forces applied by the respective finger actuators 50, translational, rotational, and/or magnification adjustments can be made. The finger actuators 52 can thus implement overlay compensation by way of adjusting the position and/or geometry of the stamp 50. The NIL tool 4 also includes a light source 54, such as a light emitting diode (LED) or array of LEDs, a semiconductor laser diode or array of semiconductor laser diodes, a gas laser, or so forth, optionally in combination with focusing, collimating, and/or other optical components. The light source 54 emits light L1 that impinges on a digital mirror device (DMD) 56 to digitally modulate the light beam L1 to form a digitally modulated light beam L2 that illuminates the IC chip being patterned. In the illustrative example, the stamp 50 is transparent for the light beam L2 so that it impinges onto the underlying IC chip. The digitally modulated light beam L2 applies different levels of light to different portions of the IC die being patterned on the semiconductor wafer 38 to generate a heat distribution in the IC chip that leads to thermal expansion or contraction of the IC chip. To provide the digital light beam modulation, the DMD 56 includes a two-dimensional array of microoptoelectromechanical (MOEM) devices each including a micromirror that can be tilted to either (i) reflect the portion of the light beam L1 onto the IC chip to illuminate a corresponding portion of the IC chip, or (ii) deflect that portion of the light beam L1 away from the corresponding portion of the IC chip so that it is not illuminated. The optics including the light source 54 and DMD 56 thus can implement overlay compensation by way of causing spatially controlled thermal expansion and/or contraction of portions of the IC chip undergoing patterning.

Metrology may be performed after the NIL step to determine any overlay error, from which updated overlay compensation terms are computed for use in performing the NIL step on subsequent wafers (feedback compensation, denoted herein as Fn-1), and/or for use in the next NIL step on the current wafer (feedforward compensation, denoted herein as Pn). Notably, the overlay compensation for the NIL step is represented by non-k-terms, such as a stamp deformation model to be implemented by force settings of the finger actuators 52 and an IC chip thermal distortion model to be implemented by digital micromirror settings the DMD 56. The metrology may in some embodiments be entirely automated, for example using an OHT or the like to transfer a FOUP or other wafer carrier from the NIL tool 4 to a microscope or other metrology tool to perform the metrology, with robotic wafer transfer apparatuses loading wafers into and unloading wafers from the respective NIL tool 4 and metrology tool.

With continuing reference to FIG. 1, the APC 6 employs both feedback (prelot) and feedforward (prelayer) overlay compensation (i.e., FF/FB control). (However, it is alternatively contemplated for the APC to instead perform only feedforward control). For an optical lithography step performed after a previous optical lithography step, the FF/FB control can be represented as:

$$\begin{matrix}Cn \\ ( k - term )\end{matrix} = \begin{matrix}Fn - 1 \\ ( k - term )\end{matrix} + \begin{matrix}Pn \\ ( k - term )\end{matrix} \qquad ( 3 )$$

In the overlay compensation of Equation (3), the term Pn is the feedforward overlay compensation, determined from metrology performed after the previous optical lithography step. For example, the metrology may comprise quantitative microscopy analysis comparing the pattern printed in the previous optical lithography step with underlying designated alignment marks or features to determine the alignment error (if any) for the previous optical lithography step. The term Pn is then the overlay compensation that would correct for this measured alignment error. In view of the foregoing, the term Pn may also be referred to as a pre-layer OVL (i.e., overlay) compensation term. It is also noted that Equation (3) is implemented for each k-term (e.g., for each k-term k₁, k₂, k₃, k₄, . . . , k₁₇, k₁₈, k₁₉, and k₂₀ in the example k-term modeling of Equations (1) and (2)).

The term Fn-1 is the feedback overlay compensation, determined from metrology performed after an instance (or instances) of the current optical lithography step performed on a previous wafer (or previous wafer lot). For example, the metrology may comprise quantitative microscopy analysis comparing the pattern printed in the current optical lithography step performed on the previous wafer (or wafer lot) with underlying designated alignment marks or features to determine the alignment error (if any) for current optical lithography step performed on the previous wafer (or wafer lot). The term Fn-1 is then the overlay compensation that would correct for this measured alignment error. In view of the foregoing, the term Fn-1 may also be referred to as a pre-lot OVL (i.e., overlay) compensation term.

The term Cn for the current optical lithography step is then calculated in Equation (3) by summing Fn-1 and Pn. The term Cn can thus also be referred to as the current lot OVL (overlay) compensation, and is the compensation for the current optical lithography step on the current semiconductor wafer. The term Cn should be a k-term as appropriate for optical lithography. Notably, Equation (3) applies to the situation in which both the current step is an optical lithography step and the previous step is an optical lithography step. Hence, all terms Cn, Fn-1, and Pn are k-terms, as appropriate for overlay compensation terms for optical lithography.

For an NIL step performed after a previous NIL step, the FF/FB control performed by the APC 6 can be represented as:

$$\begin{matrix}Cn \\ ( non - k - term )\end{matrix} = \begin{matrix}Fn - 1 \\ ( non - k - term )\end{matrix} + \begin{matrix}Pn \\ ( non - k - term )\end{matrix} \qquad ( 4 )$$

In the overlay compensation of Equation (4), the term Pn is the feedforward overlay compensation, determined from metrology performed after the previous NIL step. For example, the metrology may comprise quantitative microscopy analysis comparing the pattern printed in the previous NIL step with underlying designated alignment marks or features to determine the alignment error (if any) for the previous NIL step. The term Pn is then the overlay compensation that would correct for this measured alignment error. That is, Pn is a pre-layer OVL compensation term. It is also noted that Equation (4) is implemented for each non-k-term (e.g., each non-k-term of the stamp deformation model and IC chip thermal distortion model).

The term Fn-1 is the feedback overlay compensation, determined from metrology performed after an instance (or instances) of the current NIL step performed on a previous wafer (or previous wafer lot). For example, the metrology may comprise quantitative microscopy analysis comparing the pattern printed in the current NIL step performed on the previous wafer (or wafer lot) with underlying designated alignment marks or features to determine the alignment error (if any) for current NIL step performed on the previous wafer (or wafer lot). The term Fn-1 is then the overlay compensation that would correct for this measured alignment error. That is, the term Fn-1 is a pre-lot OVL compensation term.

The term Cn for the current NIL step is then calculated in Equation (4) by summing Fn-1 and Pn. The term Cn can thus also be referred to as the current lot OVL compensation, and is the compensation for the current NIL step on the current semiconductor wafer. The term Cn should be a non-k-term as appropriate for NIL. Notably, Equation (4) applies to the situation in which both the current step is an NIL step and the previous step is an NIL step. Hence, all terms Cn, Fn-1, and Pn are non-k-terms, as appropriate for overlay compensation terms for NIL.

A difficulty arises, however, in applying the FF/FB overlay compensation (and, more particularly, in applying the FF compensation) if optical lithography steps and NIL steps are interleaved. For example, as indicated by the legend 60 of FIG. 1, a FF/FB control pathway indicated by solid arrows is employed for the case in which the previous lithography step was an optical lithography step performed using the optical scanner 2, and the current lithography step is an NIL step performed using the NIL tool 4. In this case, the feedback term Fn-1 and the current lot OVL compensation Cn are both non-k-terms, as appropriate for the current NIL step. However, the feedforward overlay compensation term Pn 62 in this case is a k-term, because it is determined as the overlay compensation for the previous optical lithography step that would correct the overlay error determined from metrology performed after the previous optical lithography step performed on the current wafer. This term Pn 62 is computed as a k-term as it is computed as overlay compensation for an optical lithography step. This situation would result in attempting to compute Cn as:

$$\begin{matrix}Cn \\ ( non - k - term )\end{matrix} = \begin{matrix}Fn - 1 \\ ( non - k - term )\end{matrix} + \begin{matrix}Pn \\ ( k - term )\end{matrix} \qquad ( 5 )$$

In Equation (5), the lattermost feedforward (i.e., pre-layer) overlay compensation term Pn is a k-term that cannot be added to the feedback term Fn-1 which is a non-k-term.

An analogous situation occurs if an optical lithography step follows an NIL step. For example, as indicated by the legend 60 of FIG. 1, a FF/FB control pathway indicated by dashed arrows is employed for the case in which the previous lithography step was an NIL step performed using the NIL tool 4, and the current lithography step is an optical lithography step performed using the optical lithography scanner 2. In this case, the feedback term Fn-1 and the current lot OVL compensation Cn are both k-terms, as appropriate for the current optical lithography step. However, the feedforward overlay compensation term Pn 64 in this case is a non-k-term, because it is determined as the overlay compensation for the previous NIL step that would correct the overlay error determined from metrology performed after the previous NIL step performed on the current wafer. This term Pn 64 is computed as a non-k-term as it is computed as overlay compensation for an NIL step. This situation would result in attempting to compute Cn as:

$$\begin{matrix}Cn \\ ( k - term )\end{matrix} = \begin{matrix}Fn - 1 \\ ( k - term )\end{matrix} + \begin{matrix}Pn \\ ( non - k - term )\end{matrix} \qquad ( 6 )$$

In Equation (6), the lattermost feedforward (i.e., pre-layer) overlay compensation term Pn is a non-k-term that cannot be added to the feedback term Fn-1 which is a k-term.

The foregoing examples employ FF/FB control. However, it will be appreciated that the overlay compensation term incompatibilities described with reference to Equations (5) and (6) also arise if the APC employs only feedforward (FF) control. In this case, Equation (5) becomes:

$$\begin{matrix}Cn \\ ( non - k - term )\end{matrix} = \begin{matrix}Pn \\ ( k - term )\end{matrix} \qquad ( 5 a )$$

and Equation (6) becomes:

$$\begin{matrix}Cn \\ ( k - term )\end{matrix} = \begin{matrix}Pn \\ ( non - k - term )\end{matrix} \qquad ( 6 a )$$

As can be seen, the overlay compensation term incompatibilities are also present in attempting to implement the FF control of Equation (5a) or Equation (6a).

To enable the APC 6 to handle situations such as those described with reference to Equations (5) and (6), the APC 6 advantageously includes an overlay compensation terms translator 70. To this end, the APC 6 comprises the aforementioned computer or other electronic processor operatively connected with the optical scanner 2 and NIL tool 4, and programmed to perform R2R overlay compensation control including implementing the overlay compensation terms translator 70. In the case in which the previous lithography step was an optical lithography step performed using the optical scanner 2, and the current lithography step is an NIL step performed using the NIL tool 4, Equation (5) becomes:

$$\begin{matrix}Cn \\ ( non - k - term )\end{matrix} = \begin{matrix}Fn - 1 \\ ( non - k - term )\end{matrix} + \begin{matrix}T ( \begin{matrix}Pn \\ ( k - term )\end{matrix} ) \\ ( non - k - term )\end{matrix} \qquad ( 7 )$$

where in Equation (7) T( . . . ) represent a translation of the k-term Pn 62 to a corresponding non-k-term, performed by the overlay compensation terms translator 70.

In the case in which the previous lithography step was an NIL step performed using the NIL tool 4, and the current lithography step is an optical lithography step performed using the optical lithography scanner 2, Equation (6) becomes:

$$\begin{matrix}Cn \\ ( k - term )\end{matrix} = \begin{matrix}Fn - 1 \\ ( k - term )\end{matrix} + \begin{matrix}T ( \begin{matrix}Pn \\ ( non - k - term )\end{matrix} ) \\ ( k - term )\end{matrix} \qquad ( 8 )$$

where in Equation (8) T( . . . ) represent a translation of the non-k-term Pn 64 to a corresponding k-term, performed by the overlay compensation terms translator 70.

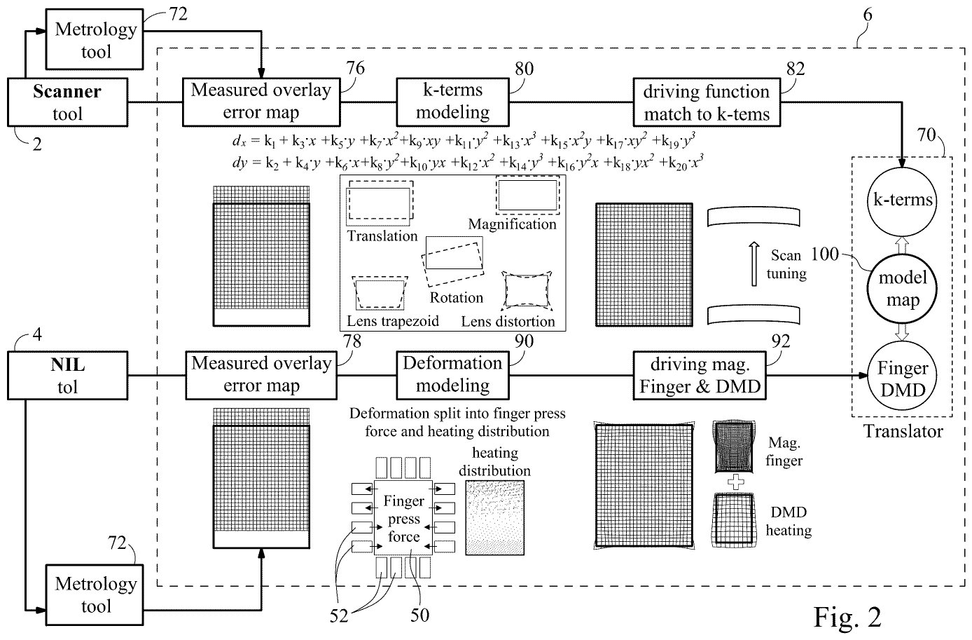

With reference now to FIG. 2, a nonlimiting illustrative embodiment of the APC 6 is shown. The APC 6 is operatively connected with the optical scanner (i.e., scanner tool) 2 and with the NIL tool 4 to supply overlay compensation terms Cn to the respective tools 2 and 4. As further shown in FIG. 2, the APC 6 is operatively connected with a metrology tool (i.e., metrology) 72 that performs metrology on the semiconductor wafer after an optical lithography step performed by the optical scanner 2; and the APC 6 is operatively connected with the metrology tool 72 that also performs metrology on the semiconductor wafer after an NIL step performed by the NIL tool 4. While FIG. 2 illustrates a single metrology tool 72 used in both cases, in some alternative embodiments different metrology tools may be used for optical lithography layers versus NIL layers. The metrology tool(s) 72 may, for example, include a scanning electron microscope (SEM), an optical diffraction measurement tool, a combination thereof, or so forth, as nonlimiting illustrative examples. In the illustrative example, the metrology tool(s) 72 generate a measured overlay error map 76 or 78. The measured overlay error map may, for example, comprise or represent a two-dimensional vector field indicating the error (as a function of x,y position) of the pattern formed by the current optical lithography or NIL step respective to designated alignment marks or features in the previous layer as determined by the metrology tool 72.

In the case of an optical lithography step performed by the optical scanner 2, the measured overlay error map 76 is modeled using k-terms modeling 80 (e.g., by fitting the polynomials of Equations (1) and (2) to the measured overlay error map 76) to generate the k-terms representing the overlay compensation for the optical lithography step. In an operation 82, the k-terms may be converted to physically realizable settings of the optical scanner 2, such as settings of the projection module 42, settings of an X-Y translation stage of the photomask holder 32, settings of an X-Y translation stage of the wafer holder 40, and/or so forth in the illustrative EUV scanner 2 of FIG. 1. The output of the operation 82 are physically realizable settings that may be input to the optical scanner 2 to set up the optical scanner 2 for performing an optical lithography step including the overlay compensation.

In the case of an NIL step performed by the NIL tool 4, the measured overlay error map 78 is modeled using deformation modeling 90 (e.g., by modeling deformation of the stamp 50 that can be obtained using the finger actuators 52 and/or heating using the DMD 56) to generate the non-k-terms representing the overlay compensation for the NIL step. In an operation 92, the non-k-terms may be converted to physically realizable settings of the NIL tool 4, such as electrical inputs to piezoelectric finger actuators 52, and electrical inputs to the MOEM devices of the DMD 56 to tilt respective micromirrors to provide the desired digitally modulated light beam L2. The output of the operation 92 are physically realizable settings that may be input to the NIL tool 4 to set up the NIL tool 4 for performing an NIL step including the overlay compensation.

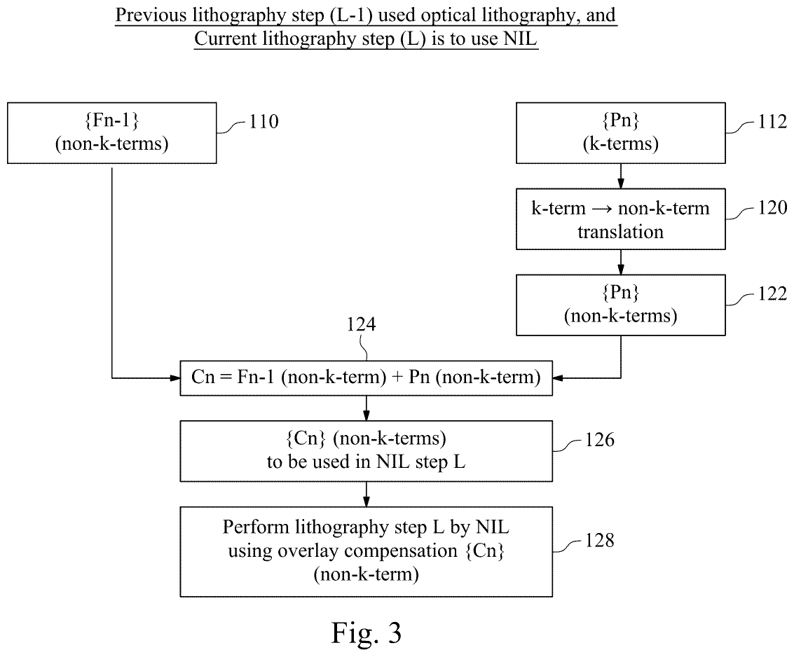

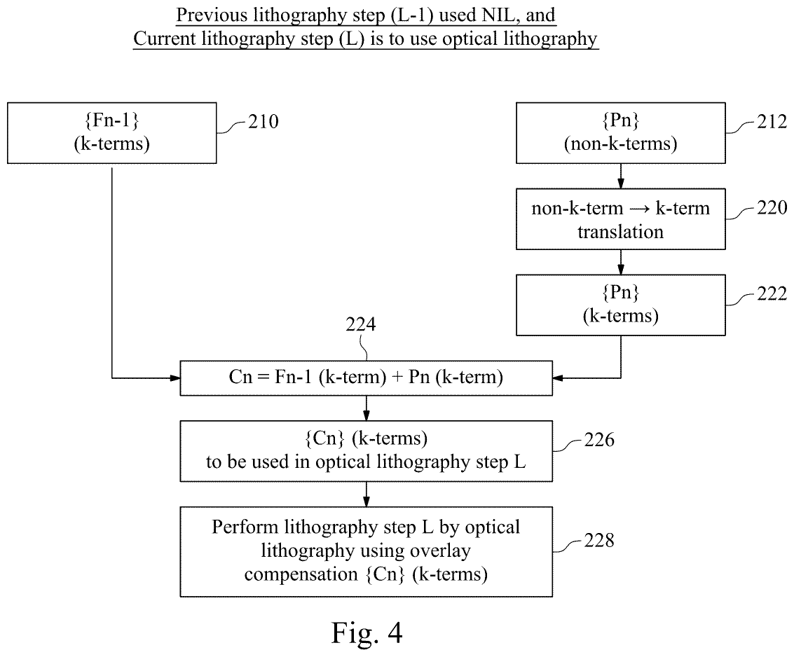

With continuing reference to FIG. 2 and with further reference to FIGS. 3 and 4, the APC 6 further includes the overlay compensation terms translator 70, which as previously described with reference to FIG. 1 translates a feedforward k-term Pn 62 of a previous optical lithography step to a non-k-term Pn for use in an upcoming NIL step; and which translates a feedforward non-k-term Pn 64 of a previous NIL step to a k-term Pn for use in an upcoming optical lithography step. FIG. 3 shows an example where the previous lithography step used optical lithography, and current lithography step is to use NIL, and FIG. 4 shows an example where the previous lithography step used NIL, and current lithography step is to use optical lithography. The translation is performed using a model map 100.

FIG. 3 diagrammatically illustrates operation of the overlay compensation terms translator 70 in an example in which the previous lithography step (designated step L−1) used optical lithography performed using the optical scanner 2, and current lithography step (designated step L) is to use NIL performed by the NIL tool 4. Here the inputs are a set of feedback overlay compensation terms {Fn-1} 110 which are non-k-terms (due to the current lithography step L being an NIL step), and a set of feedforward overlay compensation terms {Pn} 112 which are k-terms (due to the previous lithography step L−1 being an optical lithography step). The uses of braces { . . . } indicates a set of terms. For example, the set of feedforward overlay compensation k-terms {Pn} 112 may include the set of k-terms k₁, k₂, k₃, k₄, . . . , k₁₇, k₁₈, k₁₉, and k₂₀, as in the example k-term modeling of Equations (1) and (2). Likewise, the set of non-k-terms {Fn-1} 110 in this example may include the forces applied by the finger actuators 52 and the settings of the micromirrors of the DMD 56.

In an operation 120, the overlay compensation terms translator 70 translates the set of feedforward k-terms {Pn} 112 into a set of feedforward non-k-term {Pn} 122. The translation operation 120 may, in one nonlimiting illustrative example, operate as follows. The set of feedforward k-terms {Pn} 112 are transformed into a calculated overlay error map analogous to the measured overlay error map 76 of FIG. 2. To perform this transformation, an inverse of the k-terms modeling 80 is performed. As the k-terms are parameters of an overlay error polynomial equation (such as Equations (1) and (2) in the examples herein), the calculated overlay error map is computable from the set of k-terms {Pn} 112. The resulting calculated overlay error map may then be transformed into the set of non-k-terms {Pn} 122 using the deformation modeling 90 of FIG. 2. Thus, in this example, to implement the operation 120 the model map 100 includes an inverse of the k-terms model 80 inputting to the deformation model 90.

With all inputs now represented as non-k-terms, an operation 124 applies Equation (4) on a term-by-term basis to compute Cn (non-k-term)=Fn-1 (non-k-term)+Pn (non-k-term). This produces the set of overlay compensation non-k-terms {Cn} 126 to be used in the NIL step L. In an operation 128, the NIL step L is performed using the NIL tool 4. As previously noted, the computer or other electronic processor implementing the APC 6 is operatively connected with the NIL tool 4, and can therefore automatically load the control data (i.e., the set of overlay compensation non-k-terms {Cn} 126) into the NIL tool 4 to automatically perform the NIL step L.

FIG. 4 diagrammatically illustrates operation of the overlay compensation terms translator 70 in an example in which the previous lithography step (designated step L−1) used NIL performed by the NIL tool 4, and current lithography step (designated step L) is to use optical lithography performed by the optical scanner 2. Here the inputs are a set of feedback overlay compensation terms {Fn-1} 210 which are k-terms (due to the current lithography step L being an optical lithography step), and a set of feedforward overlay compensation terms {Pn} 212 which are non-k-terms (due to the previous lithography step L−1 being an NIL step). The uses of braces { . . . } again indicates a set of terms. For example, the set of feedforward overlay compensation k-terms {Pn} 112 may include the forces applied by the finger actuators 52 and the settings of the micromirrors of the DMD 56. Likewise, the set of k-terms {Fn-1} 210 may include the set of k-terms k₁, k₂, k₃, k₄, . . . , k₁₇, k₁₈, k₁₉, and k₂₀, as in the example k-term modeling of Equations (1) and (2).

In an operation 220, the overlay compensation terms translator 70 translates the set of feedforward non-k-terms {Pn} 212 into a set of feedforward k-term {Pn} 222. The translation operation 220 may, in one nonlimiting illustrative example, operate as follows. The set of feedforward non-k-terms {Pn} 212 are transformed into a calculated overlay error map analogous to the measured overlay error map 78 of FIG. 2. To perform this transformation, an inverse of the deformation modeling 90 is performed. The deformation modeling 90 uses the measured overlay error map 78 to generate the finger actuator forces and the settings for the DMD 56; in the inverse transform, the finger actuator forces and the settings for the DMD 56 are used to predict the resulting overlay error map, e.g., by using least squares optimization or another fitting method. The resulting calculated overlay error map may then be transformed into the set of k-terms {Pn} 222 using the k-terms modeling 80 of FIG. 2. Thus, in this example, to implement the operation 220 the model map 100 includes an inverse of the deformation model 90 inputting to the k-terms model 80.

With all inputs now represented as k-terms, an operation 224 applies Equation (3) on a term-by-term basis to compute Cn (k-term)=Fn-1 (k-term)+Pn (k-term). This produces the set of overlay compensation k-terms {Cn} 226 to be used in the optical lithography step L. In an operation 228, the optical lithography step L is performed using the optical scanner 2. As previously noted, the computer or other electronic processor implementing the APC 6 is operatively connected with the optical scanner 2, and can therefore automatically load the control data (i.e., the set of overlay compensation k-terms {Cn} 226) into the optical scanner 2) to automatically perform the optical lithography step L.

In the illustrative embodiments, the overlay compensation terms translator 70 is a component of, or integrated with, the APC 6. However, in other embodiments it is contemplated for the overlay compensation terms translator to be a separate component from the APC, with application programming interface (API) or similar component(s) connecting the APC with the translator. This alternative configuration advantageously enables an existing APC for a semiconductor fabrication facility to be retrofitted with the overlay compensation terms translator, for example if the facility has previously employed only optical lithography but now is acquiring an NIL tool.

In the following, some further embodiments are described.

In a nonlimiting illustrative embodiment, a method of lithography or controlling lithography is disclosed. The method includes: determining a measured overlay error map using metrology of a first pattern formed on an integrated circuit (IC) chip by a lithography step performed using a first lithography method; determining a set of feedforward terms of a first type corresponding to the first lithography method from the measured overlay error map; transforming the set of feedforward terms of the first type to a set of feedforward terms of a second type corresponding to a lithography method different from the first lithography method; determining overlay compensation for a lithography step to be performed using the second lithography method using at least the set of feedforward terms of the second type; and loading control data comprising the overlay compensation into a lithography tool configured to perform the second lithography method. In some embodiments of the method, the first lithography method is optical lithography and the set of feedforward terms of the first type is a set of feedforward k-terms, the second lithography method is nano imprint lithography (NIL) and the set of feedforward terms of the second type is a set of feedforward non-k-terms, and the lithography tool is an NIL tool. In other embodiments of the method, the first lithography method is NIL and the set of feedforward terms of the first type is a set of feedforward non-k-terms, the second lithography method is optical lithography and the set of feedforward terms of the second type is a set of feedforward k-terms, and the lithography tool is an optical scanner.

In a nonlimiting illustrative embodiment, a method of lithography comprises: performing an optical lithography step using an optical scanner to form a first pattern on an IC chip; determining a measured overlay error map using metrology for the first pattern formed on the IC chip; determining a set of feedforward k-terms from the measured overlay error map; transforming the set of feedforward k-terms to a set of feedforward non-k-terms; determining nano imprint lithography (NIL) overlay compensation using at least the set of feedforward non-k-terms; and performing an NIL step with the NIL overlay compensation using an NIL tool to form a second pattern on the IC chip.

In a nonlimiting illustrative embodiment, a method of lithography comprises: performing an NIL step using an NIL tool to form a first pattern on an IC chip; determining a measured overlay error map using metrology for the first pattern formed on the IC chip; determining a set of feedforward non-k-terms from the measured overlay error map, wherein the set of feedforward non-k-terms include finger actuator force settings for finger actuators of the NIL tool and micromirror settings of a digital mirror device (DMD) of the NIL tool; transforming the set of feedforward non-k-terms to a set of feedforward k-terms; determining optical lithography overlay compensation using at least the set of feedforward k-terms; and performing an optical lithography step with the optical lithography overlay compensation using an optical scanner to form a second pattern on the IC chip.

In a nonlimiting illustrative embodiment, in a lithographic method a measured overlay error map is determined using metrology of a first pattern formed on an integrated circuit (IC) chip by a lithography step performed using a first lithography method. A set of feedforward terms of a first type corresponding to the first lithography method are determined from the measured overlay error map, and are then transformed to a set of feedforward terms of a second type corresponding to a lithography method different from the first lithography method. Overlay compensation for a lithography step to be performed using the second lithography method is determined using at least the set of feedforward terms of the second type. The first lithography method may be optical lithography and the second lithography method may be nano imprint lithography, or vice versa.

In some further nonlimiting illustrative embodiments, one or more of the foregoing methods is implemented as a computer (or electronic processor) programmed to perform the method.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of lithography or controlling lithography, the method comprising:
determining a measured overlay error map using metrology of a first pattern formed on an integrated circuit (IC) chip by a lithography step performed using a first lithography method;
determining a set of feedforward terms of a first type corresponding to the first lithography method from the measured overlay error map;
transforming the set of feedforward terms of the first type to a set of feedforward terms of a second type corresponding to a lithography method different from the first lithography method;
determining overlay compensation for a lithography step to be performed using the second lithography method using at least the set of feedforward terms of the second type; and
loading control data comprising the overlay compensation into a lithography tool configured to perform the second lithography method.

2. The method of claim 1, wherein:
the first lithography method is optical lithography and the set of feedforward terms of the first type is a set of feedforward k-terms;
the second lithography method is nano imprint lithography (NIL) and the set of feedforward terms of the second type is a set of feedforward non-k-terms; and
the lithography tool is an NIL tool.

3. The method of claim 2, further comprising:
performing an optical lithography step using an optical scanner to form the first pattern on the IC chip; and
performing an NIL step using the NIL tool with the control data loaded to form a second pattern on the IC chip.

4. The method of claim 2, wherein the set of feedforward non-k-terms include finger actuator force settings for finger actuators of the NIL tool and micromirror settings of a digital mirror device (DMD) of the NIL tool.

5. The method of claim 4, wherein the feedforward k-terms of the set of feedforward k-terms are parameters of an overlay error polynomial equation.

6. The method of claim 4, wherein the transforming includes:
transforming the set of feedforward k-terms into a calculated overlay error map; and
using a deformation model to transform the calculated overlay error map into the finger actuator force settings for the finger actuators of the NIL tool and the micromirror settings of the DMD of the NIL tool.

7. The method of claim 2, further comprising:
receiving feedback non-k-terms representing overlay compensation used in a previous NIL step previously performed using the NIL tool;
wherein the overlay compensation is determined by a method comprising adding, on a term-by-term basis, the feedback non-k-terms and the feedforward non-k-terms of the set of feedforward non-k-terms.

8. The method of claim 1, wherein:
the first lithography method is nano imprint lithography (NIL) and the set of feedforward terms of the first type is a set of feedforward non-k-terms;
the second lithography method is optical lithography and the set of feedforward terms of the second type is a set of feedforward k-terms; and
the lithography tool is an optical scanner.

9. The method of claim 8, further comprising:
performing an NIL step using an NIL tool to form the first pattern on the IC chip; and
performing an optical lithography step using the optical scanner with the control data loaded to form a second pattern on the IC chip.

10. The method of claim 8, wherein:
the set of feedforward non-k-terms include finger actuator force settings for finger actuators of the NIL tool and micromirror settings of a digital mirror device (DMD) of an NIL tool; and
the feedforward k-terms of the set of feedforward k-terms are parameters of an overlay error polynomial equation.

11. The method of claim 10, wherein the transforming includes:
transforming the set of feedforward non-k-terms into a calculated overlay error map; and
using k-terms modeling to transform the calculated overlay error map into the set of feedforward k-terms.

12. The method of claim 8, further comprising:
receiving feedback k-terms representing overlay compensation used in a previous optical lithography step previously performed using the optical scanner;
wherein the overlay compensation is determined by a method comprising adding, on a term-by-term basis, the feedback k-terms and the feedforward k-terms of the set of feedforward k-terms.

13. A method of lithography, the method comprising:
performing an optical lithography step using an optical scanner to form a first pattern on an integrated circuit (IC) chip;
determining a measured overlay error map using metrology for the first pattern formed on the IC chip;
determining a set of feedforward k-terms from the measured overlay error map;
transforming the set of feedforward k-terms to a set of feedforward non-k-terms;
determining nano imprint lithography (NIL) overlay compensation using at least the set of feedforward non-k-terms; and
performing an NIL step with the NIL overlay compensation using an NIL tool to form a second pattern on the IC chip.

14. The method of claim 13, wherein:
the feedforward k-terms of the set of feedforward k-terms are parameters of an overlay error polynomial equation; and
the set of feedforward non-k-terms include finger actuator force settings for finger actuators of the NIL tool and micromirror settings of a digital mirror device (DMD) of the NIL tool.

15. The method of claim 14, wherein the transforming includes:
transforming the set of feedforward k-terms into a calculated overlay error map; and
using a deformation model to transform the calculated overlay error map into the finger actuator force settings for the finger actuators of the NIL tool and the micromirror settings of the DMD of the NIL tool.

16. The method of claim 13, further comprising:
receiving feedback non-k-terms obtained using metrology of a pattern formed by a previous NIL step performed using the NIL tool prior to performing the NIL step and on a semiconductor wafer that does not include the IC chip;
wherein the NIL overlay compensation is determined by adding, on a term-by-term basis, the feedback non-k-terms and the feedforward non-k-terms of the set of feedforward non-k-terms.

17. A method of lithography, the method comprising:
performing a nano imprint lithography (NIL) step using an NIL tool to form a first pattern on an integrated circuit (IC) chip;
determining a measured overlay error map using metrology for the first pattern formed on the IC chip;
determining a set of feedforward non-k-terms from the measured overlay error map, wherein the set of feedforward non-k-terms include finger actuator force settings for finger actuators of the NIL tool and micromirror settings of a digital mirror device (DMD) of the NIL tool;
transforming the set of feedforward non-k-terms to a set of feedforward k-terms;
determining optical lithography overlay compensation using at least the set of feedforward k-terms; and
performing an optical lithography step with the optical lithography overlay compensation using an optical scanner to form a second pattern on the IC chip.

18. The method of claim 17, wherein the feedforward k-terms of the set of feedforward k-terms are parameters of an overlay error polynomial equation.

19. The method of claim 17, wherein the transforming includes:
transforming the set of feedforward non-k-terms into a calculated overlay error map; and
using k-terms modeling to transform the calculated overlay error map into the set of feedforward k-terms.

20. The method of claim 17, further comprising:
receiving feedback k-terms obtained using metrology of a pattern formed by a previous optical lithography step performed using the optical scanner prior to performing the optical lithography step and on a semiconductor wafer that does not include the IC chip;
wherein the optical lithography overlay compensation is determined by adding, on a term-by-term basis, the feedback k-terms and the feedforward k-terms of the set of feedforward k-terms.
